(19) United States
(12) Patent Application Publication
(10) Pub. No.: US 2004/0026708 A1
(43) Pub. Date: Feb. 12, 2004

(54) Sub-mount for high power light emitting diode

(75) Inventor: Tzer-Perng Chen, Hsinchu City (TW)

Correspondence Address: BRUCE H. TROXELL, SUITE 1404, 5205 LEESBURG PIKE, FALLS CHURCH, VA, 22041, US

(73) Assignee: United Epitaxy Co., Ltd.

(21) Appl. No.: 10/458,264

(22) Filed: Jun. 11, 2003

(30) Foreign Application Priority Data
Aug. 9, 2002 (TW) 91118031

(51) Int. Cl. H01L 33/00; H01L 23/48

(52) U.S. Cl. 257/99; 257/778; 257/780; 257/784; 257/737

(57) ABSTRACT

A sub-mount for high power light emitting diode (LED) is disclosed. The sub-mount is a metal substrate, which is successively covered with an insulating layer and a metal layer on a first portion thereof. The flipped LED chip with an n and a p electrode on the same side is respectively, bonded to the metal layer and the exposed metal substrate.

### BACKGROUND OF THE INVENTION

1. Field of the Invention

The present invention relates to a package structure of high power light emitting diodes with input electrical power over one watt, and more particularly to an electrical & thermal conductive metal substrate provided thereto package high power III-V compound semiconductor light emitting diodes.

2. Description of the Prior Art

Generally, the light-emitting diode has the characteristics of small size, lower power consumption, longer life-time, short response time, and with excellently monochromatic color. Nowadays, applying the LED devices in the home appliance, computer and its periphery, and communication products are already very popular. Particularly, as four elements AlGaInP high brightness light emitting diode successively proposed by, HP and TOSHIBA in 1991 and the gallium nitride (GaN) blue light-emitting diode announced by Nichia Chemical corp. in 1993, proclaimed the day of fully color display using light-emitting diodes approaches. Today, the applications of the high brightness LEDs are even extended into other new areas such as traffic signal, traffic information board and dash board panel, brake light, side-marker light, tail light and high mount stop light in car. According to the research reports, the high brightness LEDs such as four elements AlGaInP LEDs with wavelength ranges from yellow-green light to red light have luminous efficiency ten times better than that of the conventional GaP red and green LEDs. Therefore, using high brightness AlGaInP LEDs to replace conventional low brightness GaP LEDs for some applications that need very high total flux, the number of LEDs that are needed can be reduced furthermore. Because the luminous efficiency of high brightness LEDs is over that of the incandescent lamps, the day of using LEDs instead of tungsten lamps to attain the purpose of lower maintenance and save electricity consumption seems to come.

Generally, the total flux generated by LED is affected by several factors, aside from increasing the external quantum efficiency of light emitting diode (LED) itself, another key factor is to maximize the current injection into the LED chips if the light output is linearly increased with the injection current. The external quantum efficiency is determined by the internal quantum efficiency and extraction efficiency. As the internal quantum efficiency of light emitting diode is concerned, several key factors are contributed to the internal quantum efficiency of light emitting diode such as the material quality, the carrier confinement and recombination, As to the light extraction efficiency, it can be improved by better current spreading capability, increasing the reflectivity of the distributed Bragg reflector or metal reflective layer, using transparent substrate, chip shaping and surface roughing techniques and so on.

As to factors of maximum injecting current, it includes the resistance of LED itself as well as the heat-dissipation capability of the LED chip submount. Poor heat-dissipation capability will reduce the maximum value injecting current a lot. In general, the glass transition temperature of the transparent glass material of epoxy for LED package body is not high enough. Thus, the operating temperature should be limited to a value much below the glass transition temperature. Otherwise, with the LED actively operating longer, the persisting heat generating will cause the temperature to exceed the epoxy glass transition temperature. As a result, the transparency of resin degrades and the light-intensity decreases. Even worse, breakdown of LED may result due to higher junction temperature caused by the bad heat dissipation. As to the resistance of the LED, it is related certainly to the light emitting area of the chip. The larger the area is, the smaller the resistance and the current density will result. Hence, large chip size will be helpful to increase the power output of LED.

Another factor relating to the resistance of LED therein is the resistance of each epitaxial layer and the barrier in the interface as well as the contact resistance of the electrode.

The room for improving each epitaxial layer and the contact resistance is quite limited. Hence, the submount might be a key factor worth to consider. In conventional packaging process, silicon substrate or Al₂O₃ substrate are quite common to be chosen as material for submount owe to its characteristics of easier to separate into individual square chip by either dicing or scribing and breaking. However, both of them are not good enough for high power heat dissipation capability. Therefore, if we could find an electrical & heat conductive substrate and a new mounting technology, the heat-dissipation capability could be enhanced significantly.

The Europe patent No. WO 01/47039 A1 issued to Wierer et al, point pointed out the facts that a ˜5° C./W reduction in thermal resistance more efficiently increases the maximum current that can be injected into the LED chip than a ˜0.5 Ω drop in series resistance of a LED device. Wierer et al devoted their efforts to the improvement of the submount and the metallization of the electrode. The submount for LED package is a silicon substrate. The gallium nitride LED chips with a transparent sapphire substrate 10 is mounted on the silicon substrate 50 in a way of up side down the chip so that the transparent sapphire substrate 10 is upward. Since the resistance of p-type contact layer is much higher than that of the n-type contact layer, the contacting area of p-type electrode is usually larger than that of n-type side to improve current spreading. The surface-mounting structure is depicted in FIG. 1. The chip comprises n-type cladding layer 11, un-doped gallium nitride active layer 13, p-type cladding layer 12, p-type electrode 20 and n-type electrode 22, as well as the aforementioned sapphire transparent substrate 10, The layer formed above the p-type electrode 20 and then-type electrode 22 is a passivation layer which is patterned to expose the electrode 20, 22. Then, the electrodes 20, 22 are coated with a welding metal 41, which usually has a low-melting point. The resulting structure is then mounted on the two solder pads 54 in terms of solder balls 60. As to the silicon substrate 50, has a dielectric layer 51 and a pattern metal layer 52 is formed upon it. The pattern metal layer 52 contains two bonding pads formed thereover.

In the example mentioned foregoing, Wierer et al proposed the technique for a LED chip mounting on the silicon submount so that the inject current capability is improved, but there are room for further improvement. For example, the thermal conductivity of silicon submount is not as good as some high thermal conductivity metal such as aluminum and copper. Besides, the thermal conductivity of silicon is getting worse as the temperature increasing. Therefore, the object of the invention is thus to propose a new package techniques by means of using the metal substrate as the submount to solve aforementioned problem

### SUMMARY OF THE INVENTION

An object of the present invention is to provide a high power LED structure for large area LED chips by means of an excellent electrical and heat conductivity metal substrate as a submount.

The invention disclosed herein is a high power output LED structure. The sub-mount is a metal substrate, which is successively covered with an insulating layer and a metal layer on a first portion thereof. The flipped LED chip with an n and a p electrode on the same side is respectively, bonded to the metal layer and the exposed metal substrate through a metal bonding layer.

Finally, the high power LED chip mounting on the submount is die-attached to the lead frame, wire-bonding to the lead and a transparent resin package body covers the LED chip and the bonding wire to protect them.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrating a LED is mounted on a silicon substrate in accordance with prior art.

FIG. 2 shows the top view of according to a preferred embodiment of the present invention, wherein the LED with n-type and p-type electrodes formed on the same side is adhered, respectively to a metal substrate and a metal film, which has an insulting layer formed uin between the metal film and the metal substrate.

FIG. 3 shows a cross-sectional view in accordance with the present invention.

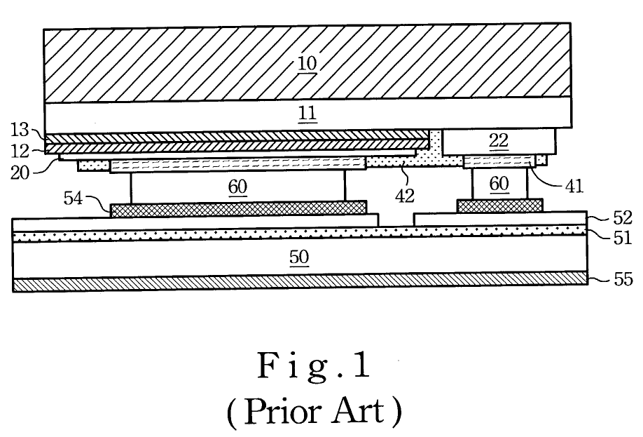

### DETAILED DESCRIPTION OF THE PREFERRED EMBODIMENT

As forgoing description in the background of invention, the non-conductive Al₂O₃ substrate or semi-conductive Si substrate is widely utilized as a submount for package due to its easier cutting performance. However, using Al₂O₃ substrate as submount material heat generated can be dissipated only through the metal layer formed upon the substrate. Hence, injecting high current density (>100 mA/cm²) does not allow. Even if it does, it is restricted only to a short time period so as to avoid degrading the transparency of the package resin. The heat dissipation capability of Si submount is much better than that of Al₂O₃ substrate but is not the best. The present invention is to disclose a metal substrate used as a submount for high power LED.

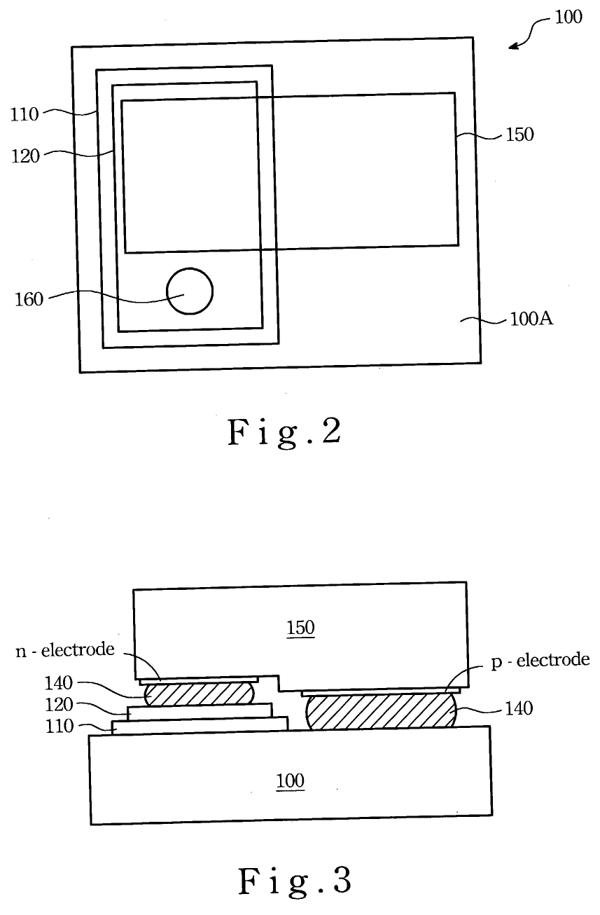

Referring to FIG. 2, at first, an insulating layer 110 is formed upon a metal substrate 100, which has good conductivity. Then a half portion of the insulating layer is removed by patterning technology. The result is shown in the figure. Atop the metal substrate is the insulating layer 110 on the first portion 110 and the remnant portion 100A still exposes the surface of the metal substrate. In a preferred embodiment, the metal substrate is selected from material such as copper or aluminum or copper or aluminum alloy. The material of the insulating layer 110 can be polyimide, BCB (B-staged bisbenzocyclobutene; BCB) SiO₂, Si₃N₄, Al₂O₃, or other insulating materials, which can bond well with copper or aluminum.

Subsequently, a metal layer 120 is blanket formed on all areas by thermal evaporation, e-beam evaporation, CVD or sputtering. A lithographic and a wet etching steps are successively followed so that the metal layer 120 on the insulting layer 110 is isolated electrically from the metal substrate 100. In a preferred embodiment, the material of the metal layer 120 can be the same material as the metal substrate 100 or different. For instance, the metal layer 120 can be Ag, Ni or Au.

Subsequently, referring to FIG. 3, a cross-sectional view, a metal bonding layer such as a solder layer, two conductive bumps or a silver paste layer 140, or the like is formed, respectively, on the metal layer 120 and the second part 100A. Thereafter, the LED 150 with an n-type and a p-type electrodes located in the same side is turned up side down and pasted to the metal bonding layer 140. Most of blue, green or blue-green LED belongs to this type. Some types of AlGaInP LEDs have the p-type and the n-type electrode located at the same side as disclosed in U.S. Pat. No. 6,462,358. Most of GaN blue and green LEDs have the p-type electrode higher than the n-type electrode in cross-sectional height, so that after LED chip is flipped, the p-type electrode is located at the second part. Next, an annealing process is performed to reflow the metal bonding layer 140. Certainly, the horizontal level can be adjusted according to the height difference of metal bonding layers so that the bonding positions for the p-type and n-type electrodes can be swapped.

Finally, the high power LED chip mounting on the submount is die-attached to the lead frame, wire-bonding to the lead and thereafter, a transparent resin body 9 (not shown) is then covered the LED chip and the bonding wire to protect them.

The advantage of this invention are as followed:

1. Since the package is a flip chip type, none of upward light be shield by electrodes.

2. Simple processes and high yield are anticipated according to method of the present invention.

3. The LED chip is almost directly mounted on an electrical and heat conductivity substrate, Cu or Al, heat dissipation capability much superior to traditional one. Therefore the metal substrate is suitable to the higher power LED.

As is understood by a person skilled in the art, the foregoing preferred embodiment of the present invention is an illustration of the present invention rather than limiting thereon. It is intended to cover various modifications and similar arrangements included within the spirit and scope of the appended claims, the scope of which should be accorded the broadest interpretation so as to encompass all such modifications and similar structure.

What is claimed is:

1. A light emitting diode chip mounting on a submount, said submount comprising:
a metal substrate;
an insulating layer formed on a first portion of said metal substrate;
a metal layer formed on said insulating layer, wherein said metal layer is insulted from said metal substrate;
a first metal bonding layer formed on said metal layer;
a second metal bonding layer formed on said metal substrate; and
a flipped light emitting diode with a first and a second electrode at the same side attached said first metal bonding layer and said second metal bonding layer;

2. The structure according to claim 1, wherein said metal substrate is selected from the group consisting of an aluminum or a copper substrate.

3. The structure according to claim 1, wherein said insulating layer is chosen from polyimide or BCB or SiO₂ or Si₃N₄.

4. The structure according to claim 1, wherein said metal bonding layer is selected from conductive bumps or a silver paste layer or a solder II layer.
